(19) United States
(12) Patent Application Publication
(10) Pub. No.: US 2025/0008799 A1
(43) Pub. Date: Jan. 2, 2025

(54) Displays Having Signal Lines with Transparent Portions

(71) Applicant: Apple Inc., Cupertino, CA (US)

(72) Inventors: Shyuan Yang, San Jose, CA (US); Abbas Jamshidi Roudbari, Saratoga, CA (US); Gihoon Choo, San Jose, CA (US); Jae Won Choi, San Jose, CA (US); Jean-Pierre S. Guillou, La Jolla, CA (US); Jonglo Park, San Diego, CA (US); Kyounghwan Kim, San Jose, CA (US); Ricardo A. Peterson, Fremont, CA (US); Sungki Lee, Sunnyvale, CA (US); Ting-Kuo Chang, San Jose, CA (US); Tsung-Ting Tsai, San Jose, CA (US); Warren S. Rieutort-Louis, Cupertino, CA (US); Yi Qiao, San Jose, CA (US); Yuchi Che, Santa Clara, CA (US); Yue Cui, Los Gatos, CA (US); Yue Jack Chu, Palo Alto, CA (US); Zhizhen Ma, Santa Clara, CA (US)

(21) Appl. No.: 18/667,776

(22) Filed: May 17, 2024

Related U.S. Application Data
(60) Provisional application No. 63/510,479, filed on Jun. 27, 2023.

(51) Int. Cl. H10K 59/131; H10K 59/121; H10K 59/65

(52) U.S. Cl. CPC H10K 59/1315; H10K 59/1213; H10K 59/65

(57) ABSTRACT

A display may include an active area with a first region and a second region. The first region may overlap an input-output component such as a camera and may have a higher transparency than the second region. The first region may have a lower pixel density than the second region. Signal lines that pass through the first region may have transparent portions that overlap the first region and opaque portions that overlap the second region. To mitigate artifacts caused by high resistance of the transparent portions of the signal lines, the signal lines may include supplemental opaque portions that are electrically connected in parallel to the transparent portions and that are routed through the second region around the first region.

This application claims the benefit of U.S. provisional patent application No. 63/510,479, filed Jun. 27, 2023, which is hereby incorporated by reference herein in its entirety.

### BACKGROUND

This relates generally to electronic devices, and, more particularly, to electronic devices with displays.

Electronic devices often include displays. For example, an electronic device may have an organic light-emitting diode (OLED) display based on organic light-emitting diode pixels. In this type of display, each pixel includes a light-emitting diode and thin-film transistors for controlling application of a signal to the light-emitting diode to produce light. The light-emitting diodes may include OLED layers positioned between an anode and a cathode.

There is a trend towards borderless electronic devices with a full-face display. These devices, however, may still need to include sensors such as cameras, ambient light sensors, and proximity sensors to provide other device capabilities. Since the display now covers the entire front face of the electronic device, the sensors will have to be placed under the display stack. In practice, however, the amount of light transmission through the display stack is very low (i.e., the transmission might be less than 20% in the visible spectrum), which severely limits the sensing performance under the display.

It is within this context that the embodiments herein arise.

### SUMMARY

An electronic device may include a display having an array of pixels and a plurality of data lines for the array of pixels. A given data line of the plurality of data lines may include a first opaque portion, a second opaque portion, a transparent portion that is interposed between and electrically connected to the first and second opaque portions, and a third opaque portion that is routed through the array of pixels to electrically connect the first and second opaque portions.

An electronic device may include an input-output component and a display having an array of pixels and signal lines. The display may have a first region and a second region, the first region may have a higher transparency than the second region, the first region may overlap the input-output component, and a signal line of the signal lines may include a first opaque portion formed on a first side of the first region, a second opaque portion formed on a second, opposing side of the first region, a transparent portion that extends between the first and second opaque portions, and a third opaque portion that extends between the first and second opaque portions.

An electronic device may include a display. The display may include an array of pixels and a signal line. Each pixel may have an emissive sub-pixel and a thin-film transistor sub-pixel, the array of pixels may have a first region with a first pixel density and a second region with a second pixel density that is greater than the first pixel density, the first region may have rows of thin-film transistor sub-pixels, and the signal line may have a plurality of opaque portions that overlap the rows of thin-film transistor sub-pixels and a plurality of transparent portions that extend between adjacent rows of thin-film transistor sub-pixels.

### BRIEF DESCRIPTION OF THE DRAWINGS

FIG. 1 is a schematic diagram of an illustrative electronic device having a display and one or more sensors in accordance with some embodiments.

FIG. 2 is a schematic diagram of an illustrative display with light-emitting elements in accordance with some embodiments.

FIG. 3 is a cross-sectional side view of an illustrative display stack that at least partially covers a sensor in accordance with some embodiments.

FIG. 4 is a cross-sectional side view of an illustrative display stack with a high-transmittance area that overlaps a sensor in accordance with some embodiments.

FIG. 5 is a top view of an illustrative display with transparent openings that overlap a sensor in accordance with some embodiments.

FIGS. 6A-6F are top views of illustrative displays showing possible positions for pixel removal regions in accordance with some embodiments.

FIG. 7 is a top view of an illustrative display with data lines having transparent portions in accordance with some embodiments.

FIG. 8 is a top view of an illustrative display with a data line having an opaque portion connected to display driver circuitry and a transparent portion in a pixel removal region in accordance with some embodiments.

FIG. 9 is a top view of an illustrative display with a data line having a transparent portion in a pixel removal region and an opaque portion that is routed around the pixel removal region and electrically connected in parallel with the transparent portion in accordance with some embodiments.

FIG. 10 is a graph of settling time as a function of position for the signal lines of FIGS. 8 and 9 in accordance with some embodiments.

FIG. 11 is a graph of change in luminance as a function of position for the signal lines of FIGS. 8 and 9 in accordance with some embodiments.

FIG. 12 is a top view of an illustrative display with a signal line having a plurality of opaque portions that overlap thin-film transistor sub-pixels and a plurality of transparent portions that extend between adjacent rows of thin-film transistor sub-pixels in accordance with some embodiments.

FIG. 13 is a cross-sectional side view of an illustrative display with a transparent conductive layer that is formed above an opaque metal layer in accordance with some embodiments.

FIG. 14 is a cross-sectional side view of an illustrative display with a transparent conductive layer that is formed below an opaque metal layer in accordance with some embodiments.

### DETAILED DESCRIPTION

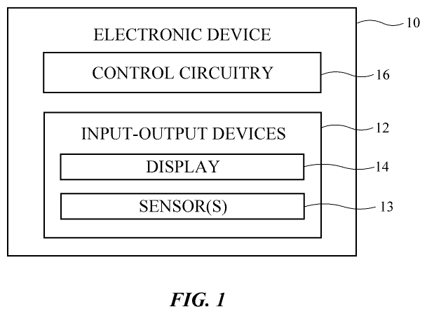

An illustrative electronic device of the type that may be provided with a display is shown in FIG. 1. Electronic device 10 may be a computing device such as a laptop computer, a computer monitor containing an embedded computer, a tablet computer, a cellular telephone, a media player, or other handheld or portable electronic device, a smaller device such as a wrist-watch device, a pendant device, a headphone or earpiece device, a device embedded in eyeglasses or other equipment worn on a user's head, or other wearable or miniature device, a display, a computer display that contains an embedded computer, a computer display that does not contain an embedded computer, a gaming device, a navigation device, an embedded system such as a system in which electronic equipment with a display is mounted in a kiosk or automobile, or other electronic equipment. Electronic device 10 may have the shape of a pair of eyeglasses (e.g., supporting frames), may form a housing having a helmet shape, or may have other configurations to help in mounting and securing the components of one or more displays on the head or near the eye of a user.

As shown in FIG. 1, electronic device 10 may include control circuitry 16 for supporting the operation of device 10. Control circuitry 16 may include storage such as hard disk drive storage, nonvolatile memory (e.g., flash memory or other electrically-programmable-read-only memory configured to form a solid-state drive), volatile memory (e.g., static or dynamic random-access memory), etc. Processing circuitry in control circuitry 16 may be used to control the operation of device 10. The processing circuitry may be based on one or more microprocessors, microcontrollers, digital signal processors, baseband processors, power management units, audio chips, application-specific integrated circuits, etc.

Input-output circuitry in device 10 such as input-output devices 12 may be used to allow data to be supplied to device 10 and to allow data to be provided from device 10 to external devices. Input-output devices 12 may include buttons, joysticks, scrolling wheels, touch pads, key pads, keyboards, microphones, speakers, tone generators, vibrators, cameras, sensors, light-emitting diodes and other status indicators, data ports, etc. A user can control the operation of device 10 by supplying commands through input resources of input-output devices 12 and may receive status information and other output from device 10 using the output resources of input-output devices 12.

Input-output devices 12 may include one or more displays such as display 14. Display 14 may be a touch screen display that includes a touch sensor for gathering touch input from a user or display 14 may be insensitive to touch. A touch sensor for display 14 may be based on an array of capacitive touch sensor electrodes, acoustic touch sensor structures, resistive touch components, force-based touch sensor structures, a light-based touch sensor, or other suitable touch sensor arrangements. A touch sensor for display 14 may be formed from electrodes formed on a common display substrate with the display pixels of display 14 or may be formed from a separate touch sensor panel that overlaps the pixels of display 14. If desired, display 14 may be insensitive to touch (i.e., the touch sensor may be omitted). Display 14 in electronic device 10 may be a head-up display that can be viewed without requiring users to look away from a typical viewpoint or may be a head-mounted display that is incorporated into a device that is worn on a user's head. If desired, display 14 may also be a holographic display used to display holograms.

Control circuitry 16 may be used to run software on device 10 such as operating system code and applications. During operation of device 10, the software running on control circuitry 16 may display images on display 14.

Input-output devices 12 may also include one or more sensors 13 such as force sensors (e.g., strain gauges, capacitive force sensors, resistive force sensors, etc.), audio sensors such as microphones, touch and/or proximity sensors such as capacitive sensors (e.g., a two-dimensional capacitive touch sensor associated with a display and/or a touch sensor that forms a button, trackpad, or other input device not associated with a display), and other sensors. In accordance with some embodiments, sensors 13 may include optical sensors such as optical sensors that emit and detect light (e.g., optical proximity sensors such as transreflective optical proximity structures), ultrasonic sensors, and/or other touch and/or proximity sensors, monochromatic and color ambient light sensors, image sensors, fingerprint sensors, temperature sensors, proximity sensors and other sensors for measuring three-dimensional non-contact gestures (“air gestures”), pressure sensors, sensors for detecting position, orientation, and/or motion (e.g., accelerometers, magnetic sensors such as compass sensors, gyroscopes, and/or inertial measurement units that contain some or all of these sensors), health sensors, radio-frequency sensors, depth sensors (e.g., structured light sensors and/or depth sensors based on stereo imaging devices), optical sensors such as self-mixing sensors and light detection and ranging (lidar) sensors that gather time-of-flight measurements, humidity sensors, moisture sensors, gaze tracking sensors, and/or other sensors. In some arrangements, device 10 may use sensors 13 and/or other input-output devices to gather user input (e.g., buttons may be used to gather button press input, touch sensors overlapping displays can be used for gathering user touch screen input, touch pads may be used in gathering touch input, microphones may be used for gathering audio input, accelerometers may be used in monitoring when a finger contacts an input surface and may therefore be used to gather finger press input, etc.).

Display 14 may be an organic light-emitting diode display, an array of discrete light-emitting diodes (microLEDs) each formed from a crystalline semiconductor die, or may be a display based on other types of display technology (e.g., liquid crystal displays). Device configurations in which display 14 is an organic light-emitting diode display are sometimes described herein as an example. This is, however, merely illustrative. Any suitable type of display may be used, if desired. In general, display 14 may have a rectangular shape (i.e., display 14 may have a rectangular footprint and a rectangular peripheral edge that runs around the rectangular footprint) or may have other suitable shapes. Display 14 may be planar or may have a curved profile.

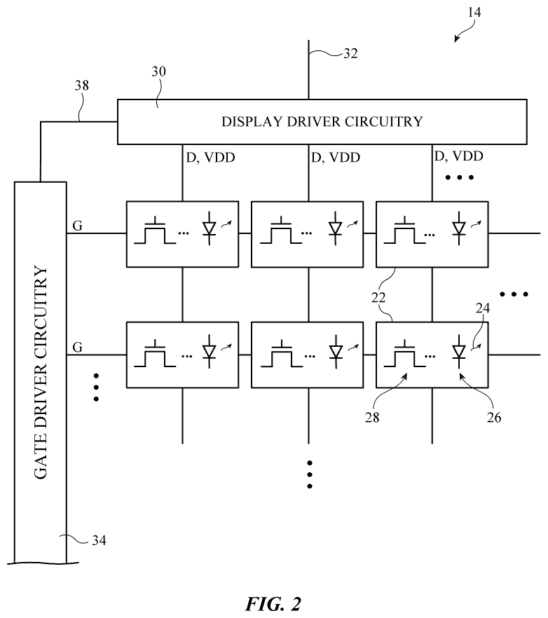

A top view of a portion of display 14 is shown in FIG. 2. As shown in FIG. 2, display 14 may have an array of pixels 22 formed on a substrate. Pixels 22 may receive data signals over signal paths such as data lines D and may receive one or more control signals over control signal paths such as horizontal control lines G (sometimes referred to as gate lines, scan lines, emission control lines, etc.). There may be any suitable number of rows and columns of pixels 22 in display 14 (e.g., tens or more, hundreds or more, or thousands or more). Each pixel 22 may include a light-emitting diode 26 that emits light 24 under the control of a pixel control circuit formed from thin-film transistor circuitry such as thin-film transistors 28 and thin-film capacitors. Thin-film transistors 28 may be polysilicon thin-film transistors, semiconducting-oxide thin-film transistors such as indium zinc gallium oxide (IGZO) transistors, or thin-film transistors formed from other semiconductors. Pixels 22 may contain light-emitting diodes of different colors (e.g., red, green, and blue) to provide display 14 with the ability to display color images or may be monochromatic pixels.

Display driver circuitry may be used to control the operation of pixels 22. The display driver circuitry may be formed from integrated circuits, thin-film transistor circuits, or other suitable circuitry. Display driver circuitry 30 of FIG. 2 may contain communications circuitry for communicating with system control circuitry such as control circuitry 16 of FIG. 1 over path 32. Path 32 may be formed from traces on a flexible printed circuit or other cable. During operation, the control circuitry (e.g., control circuitry 16 of FIG. 1) may supply display driver circuitry 30 with information on images to be displayed on display 14.

To display the images on display pixels 22, display driver circuitry 30 may supply image data to data lines D while issuing clock signals and other control signals to supporting display driver circuitry such as gate driver circuitry 34 over path 38. If desired, display driver circuitry 30 may also supply clock signals and other control signals to gate driver circuitry 34 on an opposing edge of display 14.

Gate driver circuitry 34 (sometimes referred to as row control circuitry) may be implemented as part of an integrated circuit and/or may be implemented using thin-film transistor circuitry. Horizontal control lines G in display 14 may carry gate line signals such as scan line signals, emission enable control signals, and other horizontal control signals for controlling the display pixels 22 of each row. There may be any suitable number of horizontal control signals per row of pixels 22 (e.g., one or more row control signals, two or more row control signals, three or more row control signals, four or more row control signals, etc.).

The region on display 14 where the display pixels 22 are formed may sometimes be referred to herein as the active area. Electronic device 10 has an external housing with a peripheral edge. The region surrounding the active area and within the peripheral edge of device 10 is the border region. Images can only be displayed to a user of the device in the active region. It is generally desirable to minimize the border region of device 10. For example, device 10 may be provided with a full-face display 14 that extends across the entire front face of the device. If desired, display 14 may also wrap around over the edge of the front face so that at least part of the lateral edges and/or at least part of the back surface of device 10 is used for display purposes.

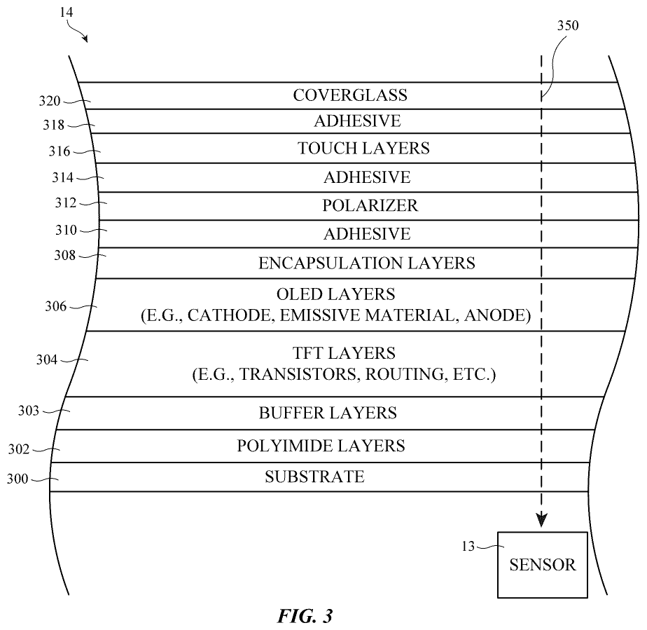

Device 10 may include a sensor 13 mounted behind display 14 (e.g., behind the active area of the display). FIG. 3 is a cross-sectional side view of an illustrative display stack of display 14 that at least partially covers a sensor in accordance with an embodiment. As shown in FIG. 3, the display stack may include a substrate such as substrate 300. Substrate 300 may be formed from glass, metal, plastic, ceramic, sapphire, or other suitable substrate materials. In some arrangements, substrate 300 may be an organic substrate formed from polyethylene terephthalate (PET) or polyethylene naphthalate (PEN) (as examples). One or more polyimide (PI) layers 302 may be formed over substrate 300. The polyimide layers may sometimes be referred to as an organic substrate (e.g., substrate 300 is a first substrate layer and substrate 302 is a second substrate layer). The surface of substrate 302 may optionally be covered with one or more buffer layers 303 (e.g., inorganic buffer layers such as layers of silicon oxide, silicon nitride, amorphous silicon, etc.).

Thin-film transistor (TFT) layers 304 may be formed over inorganic buffer layers 303 and organic substrates 302 and 300. The TFT layers 304 may include thin-film transistor circuitry such as thin-film transistors, thin-film capacitors, associated routing circuitry, and other thin-film structures formed within multiple metal routing layers and dielectric layers. Organic light-emitting diode (OLED) layers 306 may be formed over the TFT layers 304. The OLED layers 306 may include a diode cathode layer, a diode anode layer, and emissive material interposed between the cathode and anode layers. The OLED layers may include a pixel definition layer that defines the light-emitting area of each pixel. The TFT circuitry in layer 304 may be used to control an array of display pixels formed by the OLED layers 306.

Circuitry formed in the TFT layers 304 and the OLED layers 306 may be protected by encapsulation layers 308. As an example, encapsulation layers 308 may include a first inorganic encapsulation layer, an organic encapsulation layer formed on the first inorganic encapsulation layer, and a second inorganic encapsulation layer formed on the organic encapsulation layer. Encapsulation layers 308 formed in this way can help prevent moisture and other potential contaminants from damaging the conductive circuitry that is covered by layers 308. Substrate 300, polyimide layers 302, buffer layers 303, TFT layers 304, OLED layers 306, and encapsulation layers 308 may be collectively referred to as a display panel.

One or more polarizer films 312 may be formed over the encapsulation layers 308 using adhesive 310. Adhesive 310 may be implemented using optically clear adhesive (OCA) material that offer high light transmittance. One or more touch layers 316 that implement the touch sensor functions of touch-screen display 14 may be formed over polarizer films 312 using adhesive 314 (e.g., OCA material). For example, touch layers 316 may include horizontal touch sensor electrodes and vertical touch sensor electrodes collectively forming an array of capacitive touch sensor electrodes. Lastly, the display stack may be topped off with a cover glass layer 320 (sometimes referred to as a display cover layer 320) that is formed over the touch layers 316 using additional adhesive 318 (e.g., OCA material). display cover layer 320 may be a transparent layer (e.g., transparent plastic or glass) that serves as an outer protective layer for display 14. The outer surface of display cover layer 320 may form an exterior surface of the display and the electronic device that includes the display.

Still referring to FIG. 3, sensor 13 may be formed under the display stack within the electronic device 10. As described above in connection with FIG. 1, sensor 13 may be an optical sensor such as a camera, proximity sensor, ambient light sensor, fingerprint sensor, or other light-based sensor. In some cases, sensor 13 may include a light-emitting component that emits light through the display. Sensor 13 may therefore sometimes be referred to as input-output component 13. Input-output component 13 may be a sensor or a light-emitting component (e.g., that is part of a sensor). The performance of input-output component 13 depends on the transmission of light traversing through the display stack, as indicated by arrow 350. A typical display stack, however, has fairly limited transmission properties. For instance, more than 80% of light in the visible and infrared light spectrum might be lost when traveling through the display stack, which makes sensing under display 14 challenging.

Each of the multitude of layers in the display stack contributes to the degraded light transmission to sensor 13. In particular, the dense thin-film transistors and associated routing structures in TFT layers 304 of the display stack contribute substantially to the low transmission. In accordance with an embodiment, at least some of the display pixels may be selectively removed in regions of the display stack located directly over sensor(s) 13. Regions of display 14 that at least partially cover or overlap with sensor(s) 13 in which at least a portion of the display pixels have been removed are sometimes referred to as pixel removal regions, low density pixel regions, or high transmittance regions. Removing and/or shrinking display pixels (e.g., removing transistors and/or capacitors associated with one or more sub-pixels) in the pixel removal regions can drastically help increase transmission and improve the performance of the under-display sensor 13. In addition to removing display pixels, portions of additional layers such as polyimide layers 302 and/or substrate 300 may be removed for additional transmission improvement. Polarizer 312 may also be bleached for additional transmission improvement.

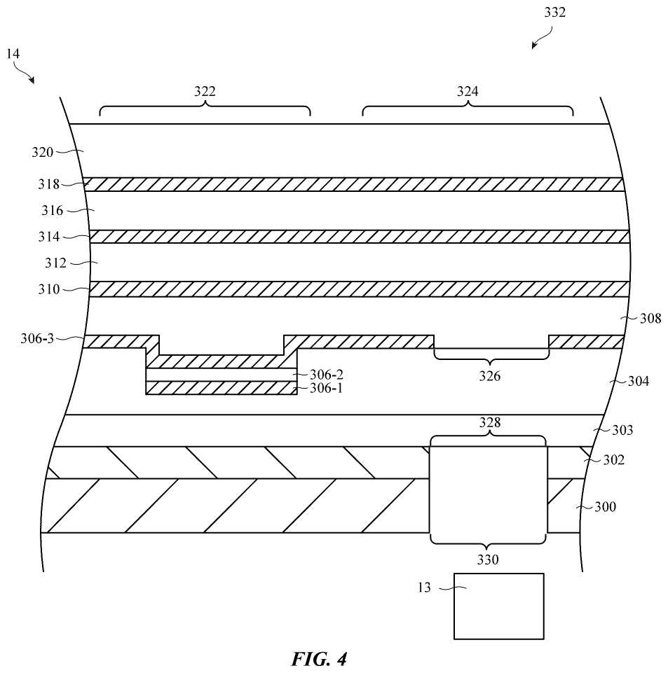

FIG. 4 is a cross-sectional side view of an illustrative display showing how pixels may be removed in a pixel removal region 332 to increase transmission through the display. As shown in FIG. 4, display 14 may include a pixel region 322 and a high-transmittance area 324. In the pixel region 322, the display may include a pixel formed from emissive material 306-2 that is interposed between an anode 306-1 and a cathode 306-3. Signals may be selectively applied to anode 306-1 to cause emissive material 306-2 to emit light for the pixel. Circuitry in thin-film transistor layer 304 may be used to control the signals applied to anode 306-1.

In high-transmittance area 324, anode 306-1 and emissive material 306-2 may be omitted. Without the high-transmittance area, an additional pixel may be formed in area 324 adjacent to the pixel in area 322. However, to increase the transmittance of light to sensor 13 under the display, the pixels in area 324 are removed. The absence of emissive material 306-2 and anode 306-1 may increase the transmittance through the display stack. Additional circuitry within thin-film transistor layer 304 may also be omitted in high-transmittance area 324 to increase transmittance.

Additional transmission improvements through the display stack may be obtained by selectively removing additional components from the display stack in high-transmittance area 324. As shown in FIG. 4, a portion of cathode 306-3 may be removed in high-transmittance area 324. This results in an opening 326 in the cathode 306-3. Said another way, the cathode 306-3 may have conductive material that defines an opening 326 in the pixel removal region. Removing the cathode in this way allows for more light to pass through the display stack to sensor 13. Cathode 306-3 may be formed from any desired conductive material. The cathode may be removed via etching (e.g., laser etching or plasma etching). Alternatively, the cathode may be patterned to have an opening in high-transmittance area 324 during the original cathode deposition and formation steps.

Polyimide layers 302 may be removed in high-transmittance area 324 in addition to cathode layer 306-3. The removal of the polyimide layers 302 results in an opening 328 in the pixel removal region. Said another way, the polyimide layer may have polyimide material that defines an opening 328 in the high-transmittance region. The polyimide layers may be removed via etching (e.g., laser etching or plasma etching). Alternatively, the polyimide layers may be patterned to have an opening in high-transmittance area 324 during the original polyimide formation steps. Removing the polyimide layer 302 in high-transmittance area 324 may result in additional transmittance of light to sensor 13 in high-transmittance area 324.

Substrate 300 may be removed in high-transmittance area 324 in addition to cathode layer 306-3 and polyimide layer 302. The removal of the substrate 300 results in an opening 330 in the high-transmittance area. Said another way, the substrate 300 may have material (e.g., PET, PEN, etc.) that defines an opening 330 in the pixel removal region. The substrate may be removed via etching (e.g., with a laser). Alternatively, the substrate may be patterned to have an opening in high-transmittance area 324 during the original substrate formation steps. Removing the substrate 300 in high-transmittance area 324 may result in additional transmittance of light in high-transmittance area 324. The polyimide opening 328 and substrate opening 330 may be considered to form a single unitary opening. When removing portions of polyimide layer 302 and/or substrate 300, inorganic buffer layers 303 may serve as an etch stop for the etching step. Openings 328 and 330 may be filled with air or another desired transparent filler.

In addition to having openings in cathode 306-3, polyimide layers 302, and/or substrate 300, the polarizer 312 in the display may be bleached for additional transmittance in the pixel removal region.

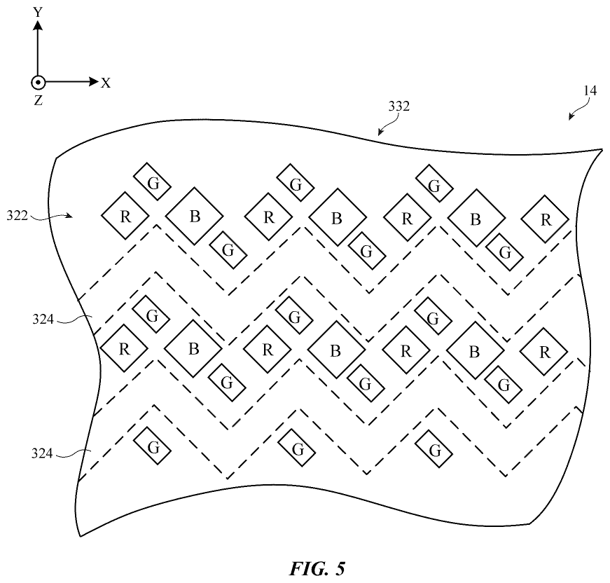

FIG. 5 is a top view of an illustrative display showing how high-transmittance areas may be incorporated into a pixel removal region 332 of the display. As shown, the display may include a plurality of pixels. In FIG. 5, there are a plurality of red pixels (R), a plurality of blue pixels (B), and a plurality of green pixels (G). The red, blue, and green pixels may be arranged in any desired pattern. Different nomenclature may be used to refer to the red, green, and blue pixels in the display. As one option, the red, blue, and green pixels may be referred to simply as pixels. As another option, the red, blue, and green pixels may instead be referred to as red, blue, and green sub-pixels (or emissive sub-pixels). In this example, a group of sub-pixels of different colors may be referred to as a pixel. In high-transmittance areas 324, no sub-pixels are included in the display (even though sub-pixels would normally be present if the normal sub-pixel pattern was followed).

To provide a uniform distribution of sub-pixels across the display surface, an intelligent pixel removal process may be implemented that systematically eliminates the closest sub-pixel of the same color (e.g., the nearest neighbor of the same color may be removed). The pixel removal process may involve, for each color, selecting a given sub-pixel, identifying the closest or nearest neighboring sub-pixels of the same color (in terms of distance from the selected sub-pixel), and then eliminating/omitting those identified sub-pixels in the final pixel removal region. With this type of arrangement, there may be high-transmittance areas in the pixel removal region, allowing a sensor or light-emitting component to operate through the display in the pixel removal region. Additionally, because some of the pixels remain present in the pixel removal region (e.g., 50% of the pixels in the layout of FIG. 5), the pixel removal region may not have a perceptibly different appearance from the rest of the display for a viewer.

As shown in FIG. 5, display 14 may include high-transmittance areas 324. Each high-transmittance area 324 may have pixels removed in that area. Each high-transmittance area also has an increased transparency compared to pixel region 322. The high-transmittance areas 324 may sometimes be referred to as transparent windows 324, transparent display windows 324, transparent openings 324, transparent display openings 324, etc. The transparent display windows may allow for light to be transmitted through the display to an underlying sensor or for light to be transmitted through the display from a light source underneath the display. The transparency of transparent openings 324 (for visible and/or infrared light) may be greater than 25%, greater than 30%, greater than 40%, greater than 50%, greater than 60%, greater than 70%, greater than 80%, greater than 90%, etc. The transparency of transparent openings 324 may be greater than the transparency of pixel region 322. The transparency of pixel region 322 may be less than 25%, less than 20%, less than 10%, less than 5%, etc. The pixel region 322 may sometimes be referred to as opaque display region 322, opaque region 322, opaque footprint 322, etc. Opaque region 322 includes light emitting pixels R, G, and B, and blocks light from passing through the display.

The pattern of pixels (322) and high-transmittance areas (324) in FIG. 5 is merely illustrative. The pattern of sub-pixels and pixel removal regions in FIG. 5 is also merely illustrative. In FIG. 5, the display edge may be parallel to the X axis or the Y axis. The front face of the display may be parallel to the XY plane such that a user of the device views the front face of the display in the Z direction. In FIG. 5, every other sub-pixel may be removed for each color. The resulting pixel configuration has 50% of the sub-pixels removed. In FIG. 5, the remaining pixels follow a zigzag pattern across the display (with two green sub-pixels for every one red or blue sub-pixel). In FIG. 5, the sub-pixels have edges angled relative to the edges of the display (e.g., the edges of the sub-pixels are at non-zero, non-orthogonal angles relative to the X-axis and Y-axis). This example is merely illustrative. If desired, each individual sub-pixel may have edges parallel to the display edge, a different proportion of pixels may be removed for different colors, the remaining pixels may follow a different pattern, etc.

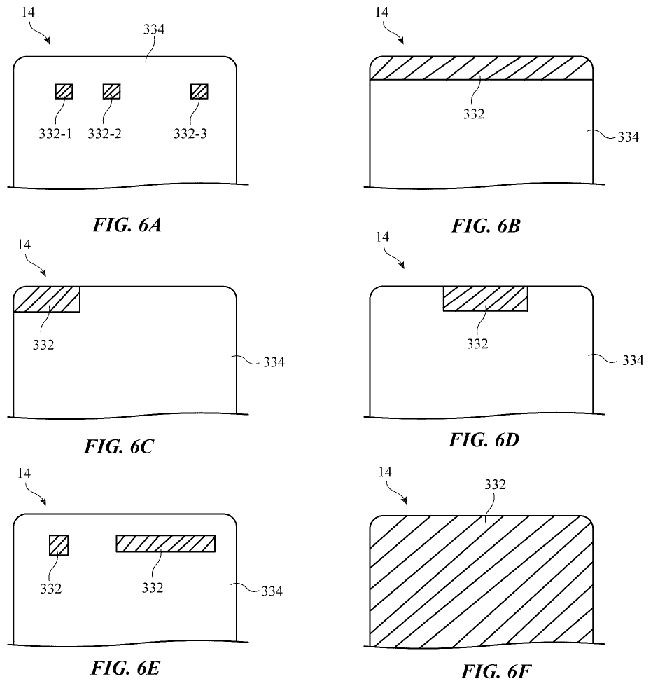

In general, the display sub-pixels may be partially removed from any region(s) of display 14. FIGS. 6A-6F are front views showing how display 14 may have one or more localized pixel removal regions in which the sub-pixels are selectively removed. The example of FIG. 6A illustrates various local pixel removal regions 332 (sometimes referred to as low pixel density regions or high-transmittance region 332) physically separated from one another (i.e., the various pixel removal regions 332 are non-continuous) by full pixel density region 334. The full pixel density region 334 (sometimes referred to as full pixel density area 334) does not include any transparent windows 324 (e.g., none of the sub-pixels are removed and the display follows the pixel pattern without modifications). The full pixel density region 334 has a higher pixel density (pixels per unit area) than low pixel density regions 332. The three pixel removal regions 332-1, 332-2, and 332-3 in FIG. 6A might for example correspond to three different sensors formed underneath display 14 (with one sensor per pixel removal region).

The example of FIG. 6B illustrates a continuous pixel removal region 332 formed along the top border of display 14, which might be suitable when there are many optical sensors positioned near the top edge of device 10. The example of FIG. 6C illustrates a pixel removal region 332 formed at a corner of display 14 (e.g., a rounded corner area of the display). In some arrangements, the corner of display 14 in which pixel removal region 332 is located may be a rounded corner (as in FIG. 6C) or a corner having a substantially 90° corner. The example of FIG. 6D illustrates a pixel removal region 332 formed only in the center portion along the top edge of device 10 (i.e., the pixel removal region covers a recessed notch area in the display). FIG. 6E illustrates another example in which pixel removal regions 332 can have different shapes and sizes. FIG. 6F illustrates yet another suitable example in which the pixel removal region covers the entire display surface. These examples are merely illustrative and are not intended to limit the scope of the present embodiments. If desired, any one or more portions of the display overlapping with optically based sensors or other sub-display electrical components may be designated as a pixel removal region/area.

FIG. 5 shows an example of a pixel removal region where some sub-pixels are removed in favor of transparent openings in the display. FIG. 5 shows a layout for sub-pixels within the pixel removal region. It should be noted that these layouts are for the emissive layer of each sub-pixel.

Each display pixel 22 may include both a thin-film transistor layer and an emissive layer. Each emissive layer portion may have associated circuitry on the thin-film transistor layer that controls the magnitude of light emitted from that emissive layer portion. Both the emissive layer and thin-film transistor layer may have corresponding sub-pixels within the pixel. Each sub-pixel may be associated with a different color of light (e.g., red, green, and blue). The emissive layer portion for a given sub-pixel does not necessarily need to have the same footprint as its associated thin-film transistor layer portion. Hereinafter, the term sub-pixel may sometimes be used to refer to the combination of an emissive layer portion and a thin-film transistor layer portion. Additionally, the thin-film transistor layer may be referred to as having thin-film transistor sub-pixels (e.g., a portion of the thin-film transistor layer that controls a respective emissive area, sometimes referred to as thin-film transistor layer pixels, thin-film transistor layer sub-pixels or simply sub-pixels) and the emissive layer may be referred to as having emissive layer sub-pixels (sometimes referred to as emissive pixels, emissive sub-pixels or simply sub-pixels).

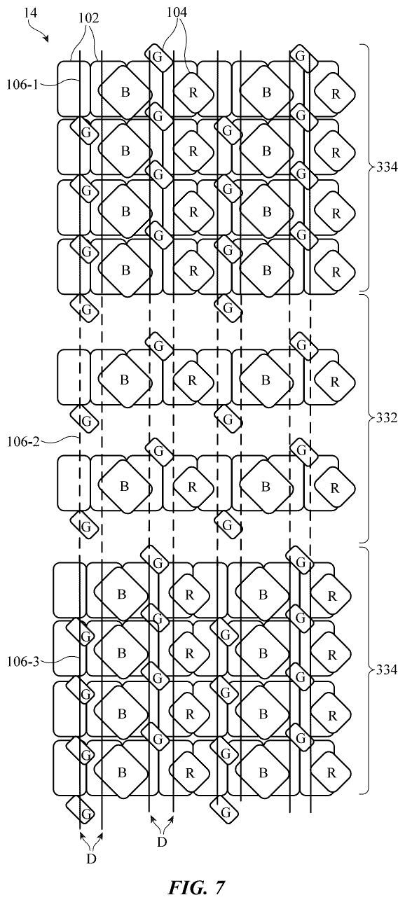

FIG. 7 is a top view of display 14 showing emissive sub-pixels and thin-film transistor sub-pixels arranged in both pixel removal region 332 and full pixel density area 334. As shown in FIG. 7, thin-film transistor sub-pixels 102 are arranged in rows. Each thin-film transistor sub-pixel 102 controls the brightness of a respective emissive sub-pixel 104. In FIG. 7, red emissive sub-pixels are identified using the label ‘R’, blue emissive sub-pixels are identified using the label ‘B’, and green emissive sub-pixels are identified using the label ‘G’.

In full pixel density area 334, the emissive sub-pixels 104 are arranged according to a pattern. In pixel removal region 332, half of the thin-film transistor sub-pixels and the emissive sub-pixels are removed relative to the full pixel density area 334. The patterns of thin-film transistor sub-pixels and emissive sub-pixels in FIG. 7 are merely illustrative. In general, any desired pattern may be used in both full pixel density area 334 and pixel removal region 332.

In some arrangements, the number of pixels per unit area in region 332 may be the same as in region 334 and one or more other modifications may be made to region 332 relative to region 334 to increase the transmittance of light through region 332 relative to region 334. For example, the footprint of emissive sub-pixels 104 and/or thin-film transistor sub-pixels 102 may be reduced in region 332 relative to region 334. Therefore, even if the number of pixels in region 332 is the same as in region 334, there may be increased transmittance through region 332 relative to region 334. Region 332 may therefore sometimes be referred to as high transmittance region 332, increased transmittance region 332, etc. Region 334 may sometimes be referred to as normal transmittance region 334, low transmittance region 334, etc.

One possible modification that may be used to improve transmittance (and, correspondingly, transparency) in region 332 is using transparent conductors instead of opaque conductors. Display 14 may have various conductive signal lines such as power supply lines, data lines, and gate lines. It may be desirable to form the conductive signal lines from opaque materials. However, opaque signal lines may undesirably reduce transmittance in region 332. Therefore, portions of signal lines in region 332 may be formed from transparent conductive material.

As shown in FIG. 7, data lines D may extend vertically across the display through both full density pixel area 334 and pixel removal region 332. To increase the transmittance in pixel removal region 332, each data line has a first portion 106-1, a second portion 106-2, and a third portion 106-3. Portions 106-1 and 106-3 (that overlap the full pixel density area 334) are formed from an opaque material (e.g., aluminum, copper, etc.) whereas portion 106-2 is formed from a transparent material (e.g., indium tin oxide). Portions 106-1 and 106-3 are depicted in FIG. 7 using solid lines whereas portion 106-2 is depicted in FIG. 7 using a dashed line. Portions 106-1 and 106-3 may have a transparency of less than 20%, less than 10%, less than 5%, less than 3%, less than 1%, etc. Portion 106-2 may have a transparency of greater than 80%, greater than 90%, greater than 95%, greater than 99%, etc.

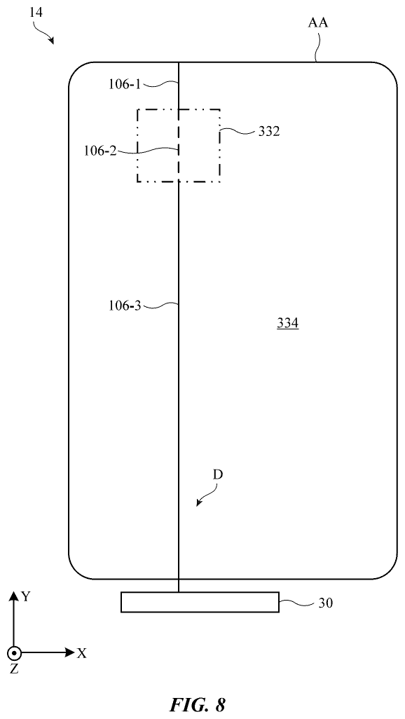

FIG. 8 is a top view of an illustrative display with a signal line having a transparent portion. As shown in FIG. 8, display 14 includes an active area AA (sometimes referred to as a light-emitting area or pixel area) with a high transmittance region 332 that is laterally surrounded by normal region 334.

Display driver circuitry 30 provides data signals to a data line D that extends across the entire active area. Each data line is coupled to a respective column of display pixels in the active area. As shown in FIG. 8, the data line D has an opaque portion 106-1 that is formed above the pixel removal region 332 (e.g., such that pixel removal region 332 is interposed between opaque portion 106-1 and display driver circuitry 30), a transparent portion 106-2 that overlaps pixel removal region 332, and an opaque portion 106-3 that is formed below the pixel removal region 332 (e.g., such that opaque portion 106-3 is interposed between pixel removal region 332 and display driver circuitry 30).

Using a transparent material for a signal line in high transmittance region 332 (as in FIGS. 7 and 8) may desirably increase the transmittance of the high transmittance region 332. However, the transparent portion 106-2 of the signal line may have a higher resistance than opaque portions 106-1 and 106-3. In opaque portions 106-1 and 106-3 of the signal line, the resistance is sufficiently low to cause a negligible impact to display performance. However, the transparent portion 106-2 of the signal line may have a resistance that is high enough to cause settling time and brightness variations in the display.

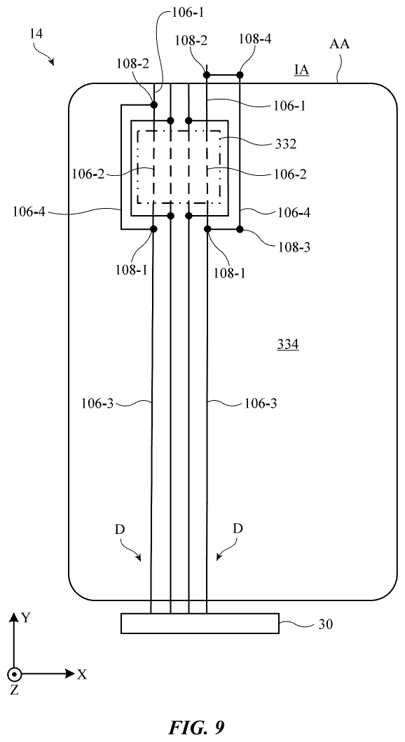

To mitigate issues caused by the increased resistance of transparent signal line portion 106-2 relative to opaque signal line portions 106-1 and 106-3, the arrangement of FIG. 9 may be used. In FIG. 9, just as in FIG. 8, each data line D that passes through region 332 has a first opaque portion 106-1 above pixel removal region 332, a transparent portion 106-2 within pixel removal region 332, and a second opaque portion 106-3 below pixel removal region 332. However, in FIG. 9 each data line that passes through region 332 additionally has a supplemental opaque portion 106-4.

As shown in FIG. 9, supplemental opaque portion 106-4 is routed around the pixel removal region to electrically connect opaque portions 106-3 and 106-1. In other words, supplemental opaque portion 106-4 forms a path that is electrically parallel to transparent portion 106-2 between opaque portions 106-3 and 106-1. Portions 106-2 and 106-4 are electrically connected in parallel between portions 106-1 and 106-3. Supplemental opaque portion 106-4 may be formed from the same material as opaque portions 106-1 and 106-3 if desired. As shown in FIG. 9, opaque portion 106-4 is routed through full pixel density region 334 of the active area of the display.

The supplemental opaque portion 106-4 is electrically connected to opaque portion 106-3 at electrical connection 108-1. The supplemental opaque portion 106-4 is electrically connected to opaque portion 106-1 at electrical connection 108-2. The active area of the display may be surrounded by an inactive area (sometimes referred to as non-light-emitting area). For each data line, each one of electrical connections 108-1 and 108-2 may be positioned within the active area AA or in the inactive area IA. In the example of FIG. 9, the electrical connections 108-1 are all within the active area of the display. The leftmost three of the electrical connections 108-2 in FIG. 9 are within the active area of the display. The rightmost of the electrical connections 108-2 in FIG. 9 is within the inactive area of the display.

In FIG. 9, supplemental data line portion 106-4 has two horizontal portions (extending parallel to the X-axis) and one vertical portion (extending parallel to the Y-axis) between the two horizontal portions. This example is merely illustrative and in general the supplemental data line portion 106-4 may have any desired path between portions 106-1 and 106-3.

If desired, some or all of supplemental data line portion 106-4 may be routed through inactive area IA instead of active area AA.

Opaque data line portions 106-1 and 106-3 may be formed from a first layer of metal within display 14. In other words, opaque data line portions 106-1 and 106-3 may be formed during the same patterning process (e.g., using the same mask). Opaque data line portions 106-1 and 106-3 may also be formed during the same patterning process (e.g., using the same mask) as data lines that do not pass through region 332. Some or all of supplemental data line portion 106-4 may be formed from the first layer of metal. Instead or in addition, some or all of supplemental data line portion 106-4 may be formed from a second layer of metal within display 14.

As one specific example, for a given data line, the two horizontal portions of portion 106-4 may be formed from the second layer of metal and portions 106-1, 106-3, and the vertical portion of portion 106-4 may be formed from the first layer of metal. Conductive vias may be used to electrically connect the first and second layers of metal as needed to ensure electrical connection between the various portions of the data line. For example, vias may be formed at electrical connections 108-1 and 108-2. Vias may also optionally be formed at electrical connection 108-3 between a first horizontal portion of supplemental data line portion 106-4 and the vertical portion of supplemental data line portion 106-4 and at electrical connection 108-4 between a second horizontal portion of supplemental data line portion 106-4 and the vertical portion of supplemental data line portion 106-4.

The sheet resistance of the material used to form signal line portion 106-2 may be greater than the sheet resistance of the material(s) used to form signal line portions 106-1, 106-3, and/or 106-4 (e.g., at least 10 times greater, at least 50 times greater, at least 100 times greater, at least 200 times greater, at least 300 times greater, at least 400 times greater, etc.).

Data lines that do not overlap pixel removal region 332 may be formed from the same material as opaque portions 106-1, 106-3, and/or 106-4. In other words, data lines that do not overlap pixel removal region 332 may be entirely opaque.

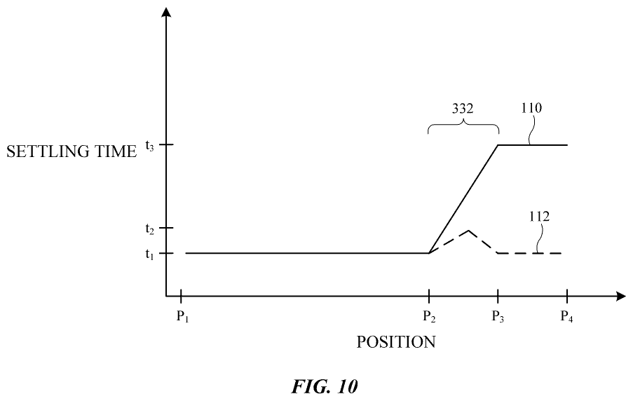

FIG. 10 shows a graph of settling time (e.g., for a pixel in a row at a given position) as a function of position across the display for data lines in both FIG. 8 and FIG. 9. The position axis reflects the position along the Y-direction from a lower edge of the display that is adjacent to the display driver circuitry (at P₁) to an upper edge of the display (at P₄). The footprint of pixel removal region 332 is defined at a lower edge by position P₂ and at an upper edge by position P₃.

In FIG. 10, profile 110 shows the settling time of a data line in the display of FIG. 8 that has a transparent portion 106-2 that overlaps pixel removal region 332. Profile 112 shows the settling time of a data line in the display of FIG. 9 that has a transparent portion 106-2 that overlaps pixel removal region 332 and an opaque portion 106-4 that electrically connects portions 106-1 and 106-3 on opposing sides of the pixel removal region.

The settling time of profile 110 may be t₁ between P₁ and P₂. This corresponds to portion 106-3 of the data line that is formed from an opaque, low-resistance material. Because portion 106-3 of the data line has a low resistance, the settling time between positions P₁ and P₂ is both uniform and equal to zero or near-zero (e.g., less than 1 nanosecond). However, the settling time increases from position P₂ towards position P₃ (within pixel removal region 332) due to the increased resistance of transparent portion 106-2. The settling time reaches a maximum value t₃ at the upper edge of the pixel removal region (e.g., at P₃). The settling time then remains approximately constant between P₃ and P₄ due to the low resistance material used for data line portion 106-1.

As with profile 110, the settling time of profile 112 may be t₁ between P₁ and P₂. However, in FIG. 9, opaque data line portion 106-1 is electrically connected to opaque data line portion 106-3 by supplemental data line portion 106-4. There is therefore a low resistance path between display driver circuitry 30 and opaque portion 106-1 (through supplemental portion 106-4). The settling time between positions P₁ and P₂ and between positions P₃ and P₄ is both uniform and equal to t₁ (e.g., zero or near-zero). Within the pixel removal region, the settling time gradually increases from the lower edge (P₂) of the pixel removal region towards a center of the pixel removal region and from the upper edge (P₃) of the pixel removal region towards the center of the pixel removal region. The settling time reaches a maximum value t₂ at the center of the pixel removal region.

Therefore, using the data line arrangement of FIG. 9 for data lines that have transparent portions in the pixel removal area 332 causes a lower maximum settling time (t₂) than using the data line arrangement of FIG. 8 (with maximum settling time t₃). In FIG. 9, the maximum settling time is also at a position that is centered within the pixel removal region (rather than the edge of the pixel removal region), which may make the increased settling time less noticeable. Furthermore, in contrast with the data line arrangement of FIG. 8, there is no increased settling time in pixel rows above the pixel removal region when the data line arrangement of FIG. 9 is used.

The change in settling time caused by high resistance transparent material for signal lines in the pixel removal region 332 may cause a corresponding change in luminance.

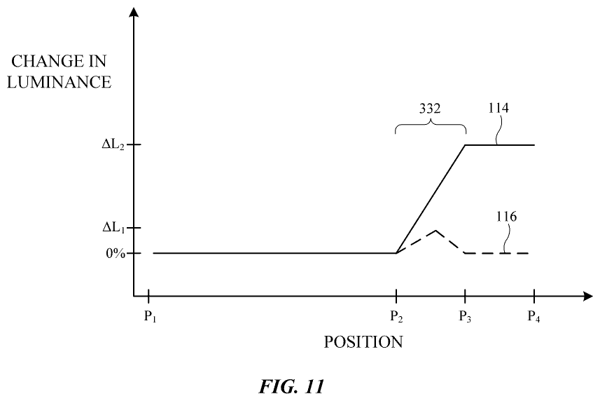

FIG. 11 shows a graph of change in luminance (e.g., for a pixel in a row at a given position) as a function of position across the display for data lines in both FIG. 8 and FIG. 9. The position axis reflects the position along the Y-direction from a lower edge of the display that is adjacent to the display driver circuitry (at P₁) to an upper edge of the display (at P₄). The footprint of pixel removal region 332 is defined at a lower edge by position P₂ and at an upper edge by position P₃.

In FIG. 11, profile 114 shows the change in luminance for a data line in the display of FIG. 8 that has a transparent portion 106-2 that overlaps pixel removal region 332. Profile 116 shows the change in luminance for a data line in the display of FIG. 9 that has a transparent portion 106-2 that overlaps pixel removal region 332 and an opaque portion 106-4 that electrically connects portions 106-1 and 106-3 on opposing sides of the pixel removal region.

The change in luminance of profile 114 may be 0% (or near-0%) between P₁ and P₂.

This corresponds to portion 106-3 of the data line that is formed from an opaque, low-resistance material. Because portion 106-3 of the data line has a low resistance, the change in luminance between positions P₁ and P₂ is both uniform and equal to zero or near-zero (e.g., less than 1%). However, the change in luminance increases from position P₂ towards position P₃ (within pixel removal region 332) due to the increased resistance of transparent portion 106-2. The change in luminance time reaches a maximum value ΔL₂ at the upper edge of the pixel removal region (e.g., at P₃). The change in luminance then remains approximately constant between P₃ and P₄ due to the low resistance material used for data line portion 106-1.

As with profile 114, the change in luminance of profile 116 may be 0% between P₁ and P₂. However, in FIG. 9, opaque data line portion 106-1 is electrically connected to opaque data line portion 106-3 by supplemental data line portion 106-4. There is therefore a low resistance path between display driver circuitry 30 and opaque portion 106-1 (through supplemental portion 106-4). The change in luminance between positions P₁ and P₂ and between positions P₃ and P₄ is both uniform and equal to 0%. Within the pixel removal region, the change in luminance gradually increases from the lower edge (P₂) of the pixel removal region towards a center of the pixel removal region and from the upper edge (P₃) of the pixel removal region towards the center of the pixel removal region. The change in luminance reaches a maximum value ΔL₁ at the center of the pixel removal region.

Therefore, using the data line arrangement of FIG. 9 for data lines that have transparent portions in the pixel removal area 332 causes a lower maximum change in luminance (ΔL₁) than using the data line arrangement of FIG. 8 (with a maximum change in luminance ΔL₂). The maximum change in luminance is also at a position that is centered within the pixel removal region (rather than the edge of the pixel removal region), which may make the change in luminance less noticeable. Furthermore, in contrast with the data line arrangement of FIG. 8, there is no change in luminance in pixel rows above the pixel removal region when the data line arrangement of FIG. 9 is used.

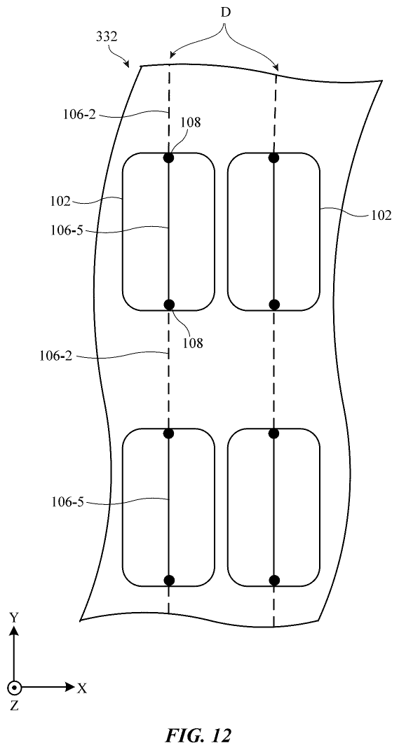

FIG. 12 is a top view of pixel removal region 332. As previously discussed, the pixel removal region 332 may include rows of thin-film transistor sub-pixels 102. The thin-film transistor sub-pixels 102 may be opaque or near-opaque. Therefore, having an opaque signal line that overlaps the thin-film transistor sub-pixel will not adversely impact the overall transmission of light through pixel removal region 332.

Data lines D in the pixel removal region may have transparent portions 106-2 and opaque portions 106-5. Transparent portions 106-2 may be formed in portions of pixel removal region 332 that do not overlap the footprint of any thin-film transistor sub-pixels (e.g., overlapping the gaps between adjacent rows of thin-film transistor sub-pixels). Opaque portions 106-5 may be formed in portions of pixel removal region 332 that overlap the footprint of a thin-film transistor sub-pixel. As previously discussed, the transparent portions 106-2 may be formed from a transparent conductive material such as indium tin oxide. Portions 106-2 may have a transparency of greater than 80%, greater than 90%, greater than 95%, greater than 99%, etc. Opaque portions 106-5 may be formed from an opaque material (e.g., aluminum, copper, etc.) and may have a transparency of less than 20%, less than 10%, less than 5%, less than 3%, less than 1%, etc.

The opaque portions 106-5 may be electrically connected to transparent portions 106-2 at electrical connections 108. Each electrical connection 108 may optionally include a conductive via.

Including opaque portions over the thin-film transistor sub-pixels may advantageously reduce the overall resistance of the signal line within pixel removal region 332 (without any adverse impact to the transparency of the pixel removal region). The concept of FIG. 12 may be applied to (and improve display performance for) the arrangement of FIG. 9 (where a supplemental data line portion 106-4 is included) or the arrangement of FIG. 8 (where a supplemental data line portion is not included).

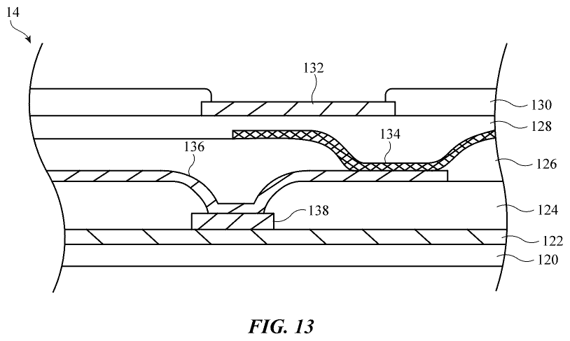

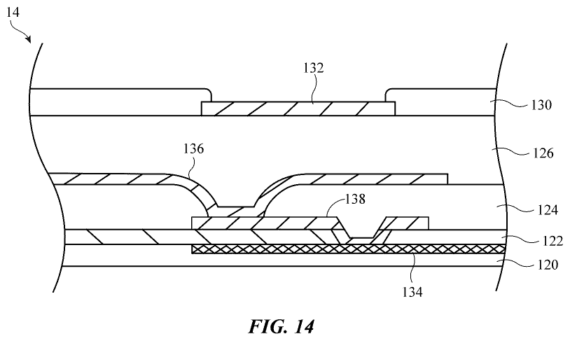

FIGS. 13 and 14 are cross-sectional side views of an illustrative display with a data line having a transparent conductive portion. As shown in FIG. 13, display 14 has one or more substrate layers such as substrates 120 and 122, a first metal layer 138 formed on the substrate, a second metal layer 136 formed over the first metal layer, a transparent conductive layer 134 formed over the second metal layer 136, and an anode 132 (e.g., an electrode that forms a part of a respective pixel 22) formed over the transparent conductive layer 134. One or more dielectric layers may be interposed between the various conductive layers in the display. FIG. 13 shows a first dielectric layer 124 between metal layers 138 and 136, a second dielectric layer 126 between metal layer 136 and transparent conductive layer 134, a third dielectric layer 128 between the transparent conductive layer 134 and anode 132, and a fourth dielectric layer 130 (sometimes referred to as a pixel definition layer) that is formed over anode 132. The pixel definition layer 130 may define a light-emitting aperture for a pixel associated with anode 132.

Opaque portions 106-1 and 106-3 of each data line may be formed from metal layer 136 (sometimes referred to as SD2). Transparent portion 106-2 of each data line may be formed from transparent conductive layer 134. The horizontal portions of opaque data line portion 106-4 may be formed from metal layer 138 (sometimes referred to as SD1). The vertical portion of opaque data line portion 106-4 may be formed from metal layer 136.

In FIG. 13, transparent conductive layer 134 is formed above metal layer 136 (e.g., between metal layer 136 and anode 132). This example is merely illustrative. In another possible arrangement, shown in FIG. 14, transparent conductive layer 134 is formed below metal layer 136. In this example, transparent conductive layer 134 is formed below metal layer 138 between substrate layers 120 and 122. Metal layer 138 may electrically connect metal layer 136 to transparent conductive layer 134. Metal layer 138 may have a via portion that extends through substrate layer 122 (sometimes referred to as dielectric layer 122) to directly contact the transparent conductive layer 134.

The examples of FIGS. 13 and 14 are merely illustrative. In general, the transparent conductive layer may have any desired position within the display stack.

It is noted that the aforementioned arrangements may be applied to any desired signal lines within the display (e.g., gate lines and/or power supply lines in addition to data lines).

The foregoing is merely illustrative and various modifications can be made by those skilled in the art without departing from the scope and spirit of the described embodiments. The foregoing embodiments may be implemented individually or in any combination.

What is claimed is:

1. An electronic device with a display having an array of pixels and a plurality of data lines for the array of pixels, wherein a given data line of the plurality of data lines comprises:
a first opaque portion;
a second opaque portion;
a transparent portion that is interposed between and electrically connected to the first and second opaque portions; and
a third opaque portion that is routed through the array of pixels to electrically connect the first and second opaque portions.

2. The electronic device defined in claim 1, wherein the first opaque portion extends in a first direction, wherein the second opaque portion extends in the first direction, and wherein the transparent portion extends in the first direction.

3. The electronic device defined in claim 2, wherein the third opaque portion has first and second portions that extend in a second direction that is orthogonal to the first direction and a third portion that extends in the first direction.

4. The electronic device defined in claim 3, wherein the first portion of the third opaque portion is electrically connected to the first opaque portion, wherein the second portion of the third opaque portion is electrically connected to the second opaque portion, and wherein the third portion of the third opaque portion extends between the first and second portions of the third opaque portion.

5. The electronic device defined in claim 4, wherein the display has an active area that includes the array of pixels and an inactive area, wherein the first portion of the third opaque portion is electrically connected to the first opaque portion in the active area, and wherein the second portion of the third opaque portion is electrically connected to the second opaque portion in the active area.

6. The electronic device defined in claim 4, wherein the display has an active area that includes the array of pixels and an inactive area, wherein the first portion of the third opaque portion is electrically connected to the first opaque portion in the active area, and wherein the second portion of the third opaque portion is electrically connected to the second opaque portion in the inactive area.

7. The electronic device defined in claim 1, wherein the first, second, and third opaque portions are formed from a first material and wherein the transparent portion is formed from a second material that is different than the first material.

8. The electronic device defined in claim 7, wherein the first material has a first sheet resistance, wherein the second material has a second sheet resistance, and wherein the second sheet resistance is at least 100 times greater than the first sheet resistance.

9. The electronic device defined in claim 1, wherein the transparent portion is formed from indium tin oxide.

10. The electronic device defined in claim 1, further comprising:
an input-output component, wherein the display has a first region and a second region, wherein the first region has a higher transparency than the second region, and wherein the first region overlaps the input-output component.

11. The electronic device defined in claim 10, wherein the input-output component is a camera.

12. The electronic device defined in claim 10, wherein the input-output component is a light emitter.

13. The electronic device defined in claim 10, wherein the transparent portion is formed in the first region.

14. The electronic device defined in claim 13, wherein the first, second, and third opaque portions are formed in the second region.

15. The electronic device defined in claim 13, wherein the first region has first and second opposing sides and is laterally surrounded by the second region, wherein the first opaque portion is formed in the second region on the first side of the first region, wherein the second opaque portion is formed in the second region on the second side of the first region, and wherein the third opaque portion is routed around the first region and through the second region between the first and second opaque portions.

16. The electronic device defined in claim 10, wherein the first region has a first pixel density and wherein the second region has a second pixel density that is greater than the first pixel density.

17. An electronic device comprising:
an input-output component; and
a display having an array of pixels and signal lines, wherein the display has a first region and a second region, wherein the first region has a higher transparency than the second region, wherein the first region overlaps the input-output component, and wherein a signal line of the signal lines comprises:
a first opaque portion formed on a first side of the first region;
a second opaque portion formed on a second, opposing side of the first region;
a transparent portion that extends between the first and second opaque portions; and
a third opaque portion that extends between the first and second opaque portions.

18. The electronic device defined in claim 17, further comprising:
display driver circuitry that is configured to provide data to the signal line and that is formed adjacent to the array of pixels, wherein the first opaque portion is interposed between the first region and the display driver circuitry.

19. An electronic device with a display, wherein the display comprises:
an array of pixels, wherein each pixel has an emissive sub-pixel and a thin-film transistor sub-pixel, wherein the array of pixels has a first region with a first pixel density and a second region with a second pixel density that is greater than the first pixel density, and wherein the first region has rows of thin-film transistor sub-pixels; and
a signal line with a plurality of opaque portions that overlap the rows of thin-film transistor sub-pixels and a plurality of transparent portions that extend between adjacent rows of thin-film transistor sub-pixels.

20. The electronic device defined in claim 19, further comprising:
an input-output component, wherein the first region overlaps the input-output component.
